(19) United States
(12) Patent Application Publication
(10) Pub. No.: US 2005/0211464 A1
(43) Pub. Date: Sep. 29, 2005

(54) Method of microelectrode connection and connected structure of use threof

(76) Inventors: Jeong Il Byun, Gyeonggi-do (KR); Kyung Joon Lee, Gyeonggi-do (KR); Myung Kyu Lee, Gyeonggi-do (KR); Chucksin Peter, Gyeonggi-do (KR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(21) Appl. No.: 10/522,049

(22) PCT Filed: Jul. 31, 2003
(86) PCT No.: PCT/KR03/01550

§ 371 Date: Jan. 20, 2005

(30) Foreign Application Priority Data
Jan. 8, 2003 (KR) 1020030001019

(51) Int. Cl. H05K 1/14

(52) U.S. Cl. 174/259; 156/306.6

(57) ABSTRACT

Disclosed is a method for connecting microcircuits formed in a circuit board, such as a Tape Carrier Package (TCP), a Flexible Printed Circuit (FPC), a Liquid Crystal Display (LCD) or a printed circuit board using an anisotropic conductive adhesive including conductive particles, and the connection structure manufactured by the above method. The method comprises the steps of applying an insulating film layer to a circuit board having circuit patterns, and then boding them with an anisotropic conduction adhesive. The circuits that should not be connected by conductive particles included in the anisotropic conductive adhesive are prevented from a short-circuit

### TECHNICAL FIELD

The present invention relates to a microcircuit connection method and a connection structure by the same, and more particularly to a method for connecting microcircuits formed in a circuit board, such as a Tape Carrier Package (TCP), a Flexible Printed Circuit (FPC), a Liquid Crystal Display (LCD) or a printed circuit board using an anisotropic conductive adhesive including conductive particles and the connection structure manufactured by the above method.

### BACKGROUND ART

In the field of a semiconductor packaging or a liquid crystal display, an adhesive is used for fixing a chip to a board or connecting circuits to each other. In case of connecting a liquid crystal display panel with a Tape Carrier Package (TCP) or a Flexible Printed Circuit (FPC), or connecting a printed circuit board with a TCP or a FPC, an anisotropic conductive adhesive including conductive particles has been used. Recently, the anisotropic conductive adhesive is used for directly mounting a semiconductor chip to a board.

FIG. 1 is a constitutional view for showing the status of printed circuit boards before the printed circuits boards are connected according to the prior art microcircuit connection method.

As shown in FIG. 1, according to the prior art microcircuit connection method, an anisotropic conductive adhesive 3 is interposed between boards 1 and 5 under the status that circuit patterns 2-P and 4-P formed on each of the boards 1 and 5 are faced each other in order to bind the boards 1 and 5. Then, the circuit patterns are bond by pressing the circuit board sides opposite to those of the anisotropic conductive adhesive with heating the pressed circuit board sides. Here, the anisotropic conductive adhesive includes insulating adhesive component 3-1, and conductive particles 3-2 uniformly dispersed in the insulating adhesive component 3-1. This anisotropic conductive adhesive is embodied as a film or a paste.

The conductive particles 3-2 dispersed in the anisotropic conductive adhesive is classified with metal particle, metal particle coated with resin thereon, and resin particle coated with metal component thereon.

In case that the conductive particle 3-2 is metal particle, since specific gravity of the metal particle is larger than that of the insulating adhesive component, the metal particle does not disperse relatively uniformly in the insulating adhesive component. Further, since the metal particle has various diameter and higher hardness, if the circuit boards are pressed with interposing the anisotropic conductive adhesive including metal particles, the shapes of the metal particles are not transformed. Therefore, the anisotropic conductive adhesive including the metal particles decreases relatively smaller a contact area between the circuits, thereby causing the circuits to connect incompletely between their connection terminals.

Further, the prior art microcircuit connection method has a problem that it often short the circuit patterns. The problem will be more specifically explained herein below with reference to figures.

FIG. 2 is a constitutional view for showing the status of printed circuit boards after printed circuits boards are connected according to the prior art microcircuit connection method. When the anisotropic conductive adhesive including the metal particles connects the circuit boards with each other, the metal particles not only connect the circuit electrodes 2-1 and 4-1 to be connected with each other, but also form a short circuit line 6 shorting the electrodes that should not be connected. Therefore, a connection structure manufactured by the prior art method cannot be operated normally.

In order to solve the shorting problem between the electrodes of the circuit boards, metal particle is coated with resin thereon and then used for the circuit boards. However, even if the metal particle coated with resin does not short the electrodes not to be connected, since the metal particle coated with resin as a core portion is not uniform and also it has relatively larger specific gravity than that of the insulating adhesive component, it is not uniformly dispersed in the insulating adhesive component. Thus, an anisortopic conductive adhesive containing metal particle coated with resin does not properly connect the circuit boards with each other.

In order to solve the problems of the anisotropic conductive adhesive, which are caused by the variety of the metal particle and larger specific gravity, resin particle as a core portion is coated with metal component thereon and then used for the circuit boards. After the anisotropic conductive adhesive including the resin particle coated with metal component is disposed between the circuit boards, if both of the circuit boards are pressed by a predetermined pressure, a defect of electrical connection may be decreased because an area between the circuit boards is increased as the resin particle coated with metal component is transformed. Further, the resin particle coated with metal component is uniformly dispersed within the adhesive component, because the difference between the specific gravity of resin particle coated with metal component and that of the adhesive component is small. However, since the resin particle is coated with metal component, the anisotropic conductive adhesive including the resin particle coated with metal component also causes a short circuit of the electrodes that should not be connected, such that the circuit boards are not properly connected to each other.

### DISCLOSURE OF THE INVENTION

It is, therefore, a primary object to provide a microcircuit connection method using anisotropic conductive adhesive including conductive particles, which is capable of enhancing the reliability of electrical connection of the electrodes of the microcircuits, without shorting the adjacent electrodes of the microcircuit by the conductive particles, which should not be connected, and a connection structure by the method.

To accomplish this object, a method for connecting microcircuits according to the invention comprises the steps of preparing an insulating resin solution; applying the resin solution to each circuit board having circuit patterns; aligning the circuit boards to face each other so that electrodes of the circuit boards face each other, in order to connect the corresponding electrodes of the circuit patterns formed in each circuit board; interposing an anisotropic conductive adhesive between the circuit boards; applying heat and pressure so that the circuits are connected electrically and mechanically.

Further, a connection structure of microcircuits according to the invention comprises a first circuit board having first circuit patterns; a second circuit board having second circuit patterns corresponding to the first circuit patterns; conductive particles positioned between the first circuit board and the second circuit board for connecting mutually corresponding electrodes in the first circuit patterns and the second circuit patterns; an insulating component positioned between the first circuit board and the second circuit board; and an insulating film layer applied on the first and second circuit boards.

### BRIEF DESCRIPTION OF THE DRAWINGS

The above and other objects, features and advantages of the invention will be apparent from the following detailed description of the preferred embodiments of the invention in conjunction with the accompanying drawings, in which:

FIG. 1 is a constitutional view for showing the status of printed circuit boards before printed circuit boards are connected according to the prior art microcircuit connection method;

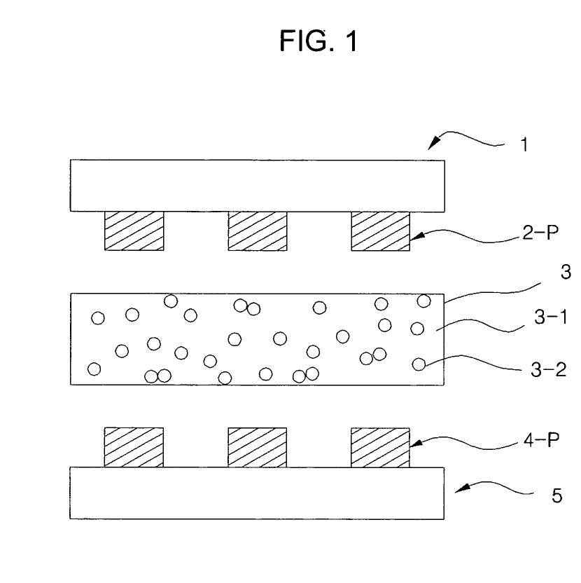

FIG. 2 is a constitutional view for showing the status of printed circuit boards after printed circuits boards are connected according to the prior art microcircuit connection method;

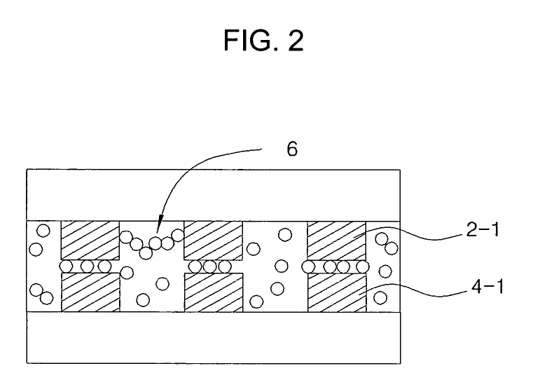

FIG. 3 is a constitutional view for showing the status of printed circuit boards before printed circuits boards are connected according to the first embodiment of the present invention;

FIG. 4 is a constitutional view for showing the status of printed circuit boards after printed circuits boards of FIG. 3 are connected;

FIG. 5 is a constitutional view for showing the status of printed circuit boards before the printed circuits boards are connected according to the second embodiment of the present invention; and

FIG. 6 is a constitutional view for showing the status of printed circuit boards after printed circuits boards of FIG. 5 are connected.

### BEST MODE FOR CARRYING OUT THE INVENTION

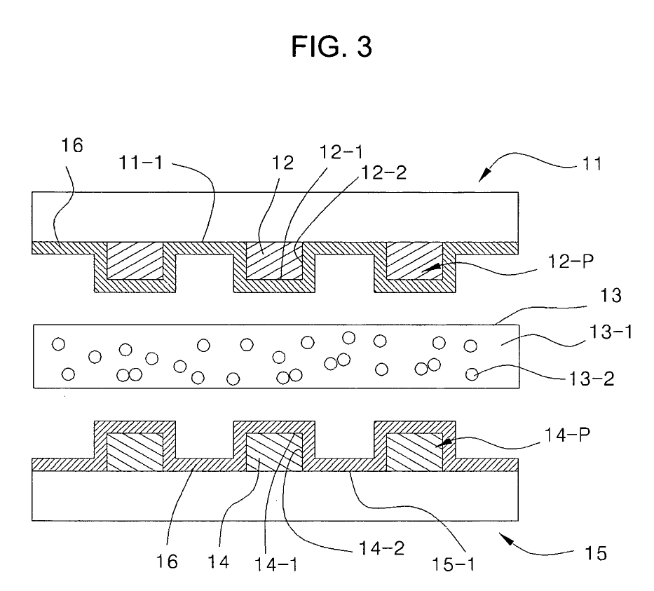

FIG. 3 is a constitutional view for showing the status of printed circuit boards before printed circuits boards are connected according to the first embodiment of the present invention. It shows the status of the printed circuit boards before a first circuit board 11 having first circuit patterns 12-P and a second circuit board 15 having second circuit patterns 14-P are bond by an anisotropic conductive adhesive 13.

The first and second circuit patterns 12-P and 14-P include electrodes 12 and 14, relatively, each of which is projected from the first and second circuit boards 11 and 15, respectively. Here, the electrodes 12 and 14 have plain portions 12-1 and 14-1 and side portions 12-2 and 14-2, respectively. The portions in which the electrodes 12 and 14 are not formed are defined as non-electrode portions or bottom portions 11-1 and 15-1.

As constructed above, the first and second circuit boards 11 and 15 include further an insulating film layer 16 having a predetermined thickness, which is coated to the plain portions 12-1 and 14-1 of the electrodes 12 and 14, the side portions 12-2 and 14-2, and the bottom portions 11-1 and 15-1, respectively.

Preferably, the plain portions 12-1 and 14-1 of the electrodes 12 and 14 are evenly formed so that the insulating film is not damaged upon pressing. Thus, a contact area between the plain portions of the electrodes becomes relatively larger.

The anisotropic conductive adhesive 13 includes insulating component 13-1 and conductive particles 13-2 relatively uniformly dispersed in the insulating component 13-1. This anisotropic conductive adhesive 13 is embodied as a film form or a paste form.

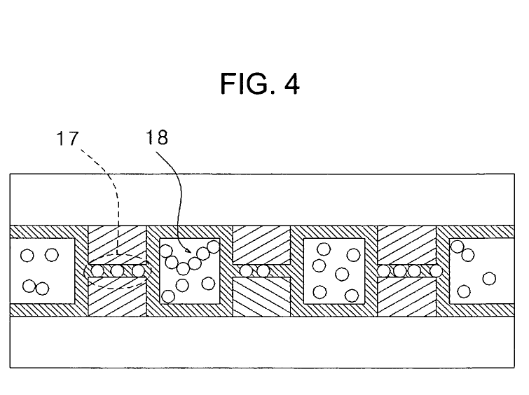

Therefore, the circuit boards having a structure of the first embodiment are connected to each other as shown in FIG. 4.

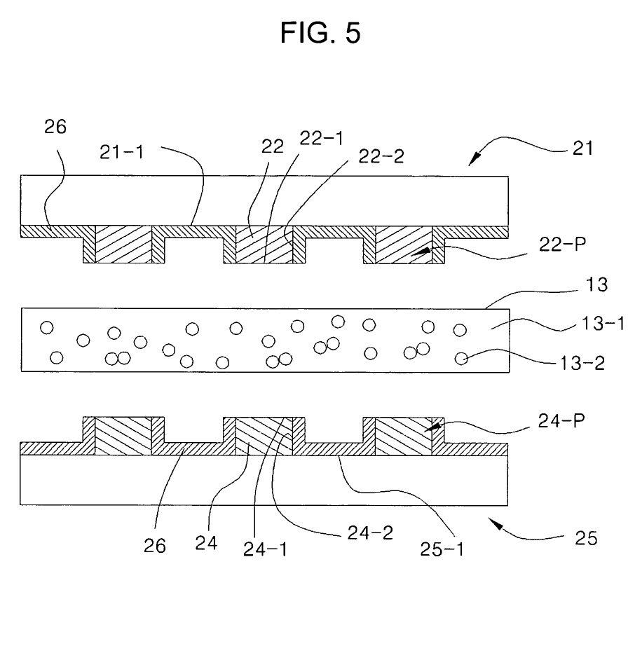

FIG. 5 is a constitutional view for showing the status of printed circuit boards before the printed circuits boards are connected according to the second embodiment of the present invention. It shows the status of the printed circuit boards before the first and second circuit boards are connected by an anisotropic conductive adhesive 13, wherein an insulating film layer 16 having a predetermined thickness is formed to the side portions 12-2 and 14-2 of the electrodes 12 and 14 and the bottom portions 11-1 and 15-1, except for the plain portions 12-1 and 14-1 of the electrodes 12 and 14 in the first embodiment.

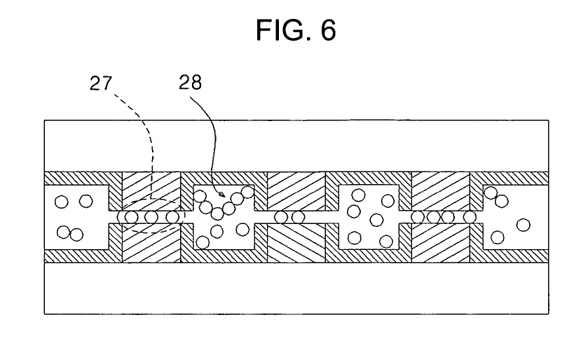

Therefore, the circuit boards having a structure of the second embodiment are connected to each other as shown in FIG. 6.

Now, the methods for manufacturing the circuit boards having the above structures and connecting the microcircuits formed in the circuit boards will be explained below.

1) Method for Connecting the Circuit Boards of FIG. 3

(1) Insulating Film Forming Step:

In the first and second circuit patterns 12-P and 14-P, the insulating film layer 16 is formed with a predetermined thickness on the plain portions 12-1 and 14-1 of the electrodes 12 and 14, on the side portions 12-2 and 14-2, and on the bottom portions 12-1 and 15-1 of the first and second circuit boards 11 and 15. Namely, the insulating film 16 is formed like that: after preparing a mixed solution by dissolving at least one of resin into a soluble solvent, the mixed solution is applied to the first and second circuit boards 12 and 15 by the method such as screen printing, solution casting or precipitation based on the process conditions. Preferably, the resin dissolved in the mixed solution may have a thermoplastic property.

Here, in order to manufacture the first and second circuit boards according to the first embodiment of FIG. 3, the formation of the insulating film layer on the plain portion and side portion of the electrode and on the bottom portion of the circuit board is accomplished after forming the circuit patterns in the step of forming the circuit patterns on the circuit board.

Meanwhile, in case of forming the insulating film layer by applying the mixed solution containing thermosetting resin to the circuit board, since the film is not softened when pressing and heating in the circuit boards bonding process, the insulating film layer is not bond to the anisotropic conductive adhesive with large bonding force, and the electrode of the circuit patterns is easily affected by corrosion. Thus, the duration period of contact of the circuit board and the reliability of contact ability are deteriorated.

Preferably, the thermoplastic resin having a softening point in the range of 60 to 150° C. may be selected from one or more in the group of consisting of polyethylene resin, ethylene copolymer resin, ethylene vinyl acetate copolymer resin, ethylene-acrylic acid copolymer resin, ethylene acrylic acid ester copolymer resin, poly amide resin, poly ester resin, styrene butadiene copolymer resin, ethylene-propylene copolymer resin, acrylic acid ester rubber, acrylonitrile-butadiene copolymer resin, phenoxy resin, thermoplastic epoxy resin, poly urethane resin, poly vinyl acetal resin and poly vinyl butilal resin.

Here, upon considering the heating temperature of the bonding process of the circuit board, if the softening point of the thermoplastic resin is less than 60° C., since the thermoplastic resin is not softened, the boding force between the circuit boards is lower, and electric connection becomes inferior. Meanwhile, if the softening point of the thermoplastic resin is more than 150° C., since the film layer formed in the side portions 12-2 of the electrode in the circuit patterns are damaged, the electrodes have a short circuit due to the conductive particles.

Preferably, the thermoplastic resin may have a softening point in the range of 80 to 120° C. In the following examples which will be explained later, which is performed within the above range, an anisotropic conduction adhesive using the above resin shows the properties that the connection resistance is small, and bonding force is large.

Preferably, the insulating film 16 has a thickness of 0.1 to 5 μm. If the thickness of the insulating film is less than 0.1 μm, the insulating film is partly peeled from the electrode in the process of pressing, and thus the electrodes is shorted by the conductive particles. Meanwhile, if the thickness of the insulating film is more than 5 μm, even though enough pressure is applied to the circuit board, since the conductive particles do not overcome the thickness, the electrodes are hardly connected to each other. Thus, the electric connection of the circuit boards becomes inferior.

Most preferably, the insulating film has a thickness of 0.3 to 3 μm. If the thickness of the insulation film is less than 0.3 μm, the insulation film is partly peeled from the electrode in the process of pressing, and thus the electrodes have a short circuit by the conductive particles. Meanwhile, if the thickness of the insulation film is more than 3 μm, even though pressure is applied to the circuit board, since the conductive particles do not overcome the thickness, the electrodes are hardly connected. The electric connection of the circuit boards becomes inferior.

(2) Bonding Step:

When pressing the circuit board together with heating, the insulating film 16 applied to the electrodes 12 and 14 of the circuit patterns that face each other is broken, and simultaneously, the conductive particles 13-2 are dispersed into the broken insulating film such that, as indicated as reference number “17,” the electrodes 12 and 14 are electrically connected to each other. At this time, since the pressure applied to the circuit board is not applied in the parallel direction to the surface of the circuit board, the insulating film formed on the side portions of the electrode in the circuit patterns is not damaged. Therefore, as indicated as reference number “18,” the adjacent electrodes are not shorted by the conductive particles 13-2.

Further, since the insulating film 16 applied to the circuit board as shown in FIG. 3 has a superior compatibility with an anisotropic conductive adhesive component, the connection structure manufactured as shown in FIG. 4 has a high reliability of the bonding force and the electric connection.

2) Method for Connecting Circuits Board of FIG. 5

(1) Insulating Film Forming Step:

As described in the above method for connecting circuit boards of FIG. 3, an insulating film 26 is formed with a predetermined thickness on the portions except for plain portions 22-1 and 24-1 of the electrodes 22 and 24 which are in the first and second circuit patterns 22-P and 24-P, respectively. The component of the insulating film, a manufacturing method thereof, and thickness thereof are the same as the conditions in the circuit boards of FIG. 3.

Here, in order to manufacture the first and second circuit boards 21 and 25 according to the second embodiment as shown in FIG. 5, the method for forming the insulating film 26 on the side portions 22-2 and 24-2 of the electrodes 22 and 24 and on the bottom portions 21-1 and 25-1 of the circuit board is accomplished by using the above applying method on the entire surface of the circuit board without removing a photo resist (not shown) attached to the circuit pattern after etching step in the process of forming the circuit patterns on the circuit board. After that, the photo resist is removed from the circuit boards, and then the insulating film 26 is formed on the side portions 22-2 and 24-2 of the electrodes 22 and 24 and on the bottom portions 21-1 and 25-1 except for the plain portions 22-1 and 24-1 of the electrodes 22 and 24.

(2) Bonding Step:

When pressing the circuit board together with heating, since the insulating film 26 is not applied to the plain portions 22-1 and 24-1 of the electrodes 22 and 24 of the circuit patterns that face each other, the conductive particles 13-2 dispersed in the anisotropic conductive adhesive is directly fixed to the plain portions 22-1, 24-1 such that, as indicated as reference number “27,” the electrodes 22-1 and 24-1 are electrically connected. At this time, since the pressure applied to the circuit board is not applied in the parallel direction to the surface of the circuit board, the insulating film formed on the side portions of the electrode in the circuit patterns is not damaged. Therefore, as indicated as reference number “28,” the adjacent electrodes are not shorted by the conductive particles 13-2.

Further, since the insulating film 26 applied to the circuit board as shown in FIG. 5 has a superior compatibility with an anisotropic conductive adhesive component, the connection structure manufactured as shown in FIG. 6 has a high reliability of the bonding force and the electric connection.

### EXAMPLE

In the following examples, connection resistance was measured to demonstrate each reliability of connection in case of TCP in which an insulating film of a thermoplastic resin is formed (Examples 1 to 4), TCP in which an insulating film of a thermosetting resin is formed (Comparative example 1), and TCP in which an insulating film is not formed (Comparative example 2). Further, in the examples and comparative examples, the bonding force was measured to demonstrate a degree of conduction of the anisotropic conductive adhesive.

The anisotropic conductive adhesive including an insulating adhesive component and conductive particles dispersed uniformly in the insulating adhesive component was coated on a poly ester film whose surface is subject to the releasing process. Then, it was dried for about 3 minutes within a fan heater with a temperature of 80° C. so that the coated layer on the film has a thickness of about 18 μm.

The conductive particle was employed from AU 205 of Sekisui Chemical Company. Here, the conductive particle with an average particle diameter of 5 μm has a structure to include resin as core portion, a nickel layer plated on the resin and a gold layer plated on the nickel layer.

Since the conductive particle has resin as a core portion, when the particle is pressed, the stress applied to the electrode may be reduced by the compression transformation of the particle. Further, the conductive particle does not have the problems which can be caused by that the size of the conductive particle is not uniform or conductive particles are not dispersed uniformly.

### Example 1

A polyester resin (Toyobo Co., Vylon 200™) was dissolved into a mixed solvent in which ketone and toluene are mixed in the weight ratio of 3:1, to prepare a solution containing 25% of solids. Subsequently, the resin solution was applied to electrode portion of TCP having a line width of 30 μm, a pitch of 60 μm, and a thickness of 18 μm, using a screen printer. And then, TCP coated with the resin solution was dried by hot wind at 70° C. for 5 minutes within an oven, thereby to obtain TCP coated with the insulating film. After that, the insulating film measures 1 μm thick using a micrometer.

### Example 2

The TCP coated with the insulating film was manufactured in the same method as Example 1 except that the vinyl acetate resin (Okong bond Co., PVAc 302™) was dissolved into a mixed solvent in which methl enthy ketone and toluene are mixed in the weight ratio of 3:1, to prepare a solution containing 25% of solids. Then, TCP coated with the insulation film having a thickness of 1 μm was manufactured using process of Example 1.

### Example 3

The TCP coated with the insulating film was manufactured in the same method as Example 1 except that the nitryl butadiene rubber (Nippon zeon Co., Nippol FN4002™) was dissolved into a mixed solvent in which methl enthy ketone and toluene are mixed in the weight ratio of 3:1, to prepare a solution containing 25% of solids. Then, TCP coated with the insulation film having a thickness of 1 μm was manufactured using process of Example 1.

### Example 4

The TCP coated with the insulating film was manufactured in the same method as the first embodiment except that the epoxy resin (Dow Co., D.E.R. 6670 ™) was dissolved into a mixed solvent in which methl enthy ketone and toluene are mixed in the weight ratio of 3:1, to prepare a solution containing 25% of solids. Then, TCP coated with the insulation film having a thickness of 1 μm was manufactured using process of Example 1.

### Comparative Example 1

An aromatic urethane acrylate (Sartomer Co., CN999™) of thermosetting resin was diluted with ethyl acetate to prepare a resin solution of 50 weight %. And then UV initiator (CIBA Co., Igacure 184™) of 3 weight % to the aromatic urethane acrylate was dissolved into the resin solution to prepare a mixed solution. Subsequently, electrode of TCP was coated with the mixed solution using a screen printer. Then, TCP coated with the mixed solution was dried by hot wind at 50° C. for 5 minutes within an oven and hardened by UV initiator for 30 seconds to obtain TCP coated with the insulating film layer having a thickness of 1 μm.

### Comparative Example 2

For this example, a prior art TCP having the electrodes on which an insulating film are not coated was adopted.

Each connection structure was formed by connecting the TCP of each Example and Comparative Example using the anisotropic conductive adhesive.

Namely, the anisotropic conductive adhesive with the polyester film was cut by a width of 1.5 mm. Then, the adhesive layer was slightly attached to ITO glass (having a surface resistance of 20 Ω/mm², and a thickness of 0.7 mm, and made in SAM-SUNG CONING Company) for 2 seconds with a temperature of 80° C. and a pressure of 0.5 Mpa. Then, the polyester film was peeled off from the anisotropic conductive adhesive attached to the ITO glass. Then, TCP having a line width of 30 μm, a pitch of 60 μm, and an electrode thickness of 18 μm with the insulating layer made from Examples and Comparative Examples and TCP which is not coated with the insulating layer were slightly bonded to the anisotropic conductive adhesive of the ITO glass. Then, it was treated by the thermo compression for 15 seconds with a temperature of 160° C. and a pressure of 3 Mpa. As a result, connection structures bonded by the anisotropic conductive adhesive were obtained.

The connection resistance and bonding force of the connection structures were measured.

First of all, for the connection resistance, an initial resistance value and a resistance value after leaving alone for 100 hours with a temperature of 85° C. and a relative humidity of 85RH % were measured.

The results are reported in the following Table 1.

TABLE 1

| | Resistance value | |
|---|---|---|
| | Initial resistance | Resistance value (Ω) after leaving alone |
| Case | value(Ω) | for 100 hours with 85° C. and 85 RH % |
| Example 1 | 2.2 | 2.4 |
| Example 2 | 2.1 | 2.7 |
| Example 3 | 2.6 | 3.5 |
| Example 4 | 2.5 | 2.6 |
| Comparative | OFF | OFF |
| example 1 | | |
| Comparative | 2.1 | 16.5 |
| example 2 | | |

As described in Table 1, the initial values in Examples 1 to 4 were relatively lower in the range of 2.1 to 2.6 Ω with comparison to Comparative Example 2 treated without coating the insulating layer, whereas an initial resistance value is not shown in Comparative Example 1 treated with the thermosetting resin.

The reason why the initial connection resistance not shown in case of applying the thermosetting resin is that the insulating layer are not damaged by the heat and pressure applied in the initial step of the circuit connection process and the conductive particles can not electrically connect between two circuits.

On the contrary, in case of prosecuting the insulating film treatment with the thermoplastic resin, since the insulating film is broken in the initial step of the connection process, the connection resistance is considered to have relatively low resistance value. Thus, if the thermoplastic resin is adopted for the insulating film treatment, there is no problem as to the initial conduction.

Further, regarding the connection resistance value after leaving alone for 100 hours with a temperature of 85° C. and a relative humidity of 85RH %, the resistance value for the comparative example 2 was considerably increased, whereas the resistance for the comparative example 1 had no resistance value. The reason is considered that the moisture penetrates into the electrode portion under the condition of high temperature and high humidity, and thus the electrode is eroded.

However, since the connection resistance value for Examples 1 to 4 are slightly increased, it is considered that the insulating film comprising the thermoplastic resin prevents the erosion of the electrode due to the moisture. Thus, it is determined that the reliability for maintaining the conduction is superior even under the severe circumstance for a long time.

For the bonding force, an initial bonding force value and a bonding force value after leaving alone for 100 hours with a temperature of 85° C. and a relative humidity of 85RH % were measured.

The results are reported in the following Table 2.

TABLE 2

| | Measuring value of Bonding force | |
|---|---|---|
| | Initial | Measuring value of Bonding force |
| | value | (kgf/cm) after leaving alone for 100 hours |
| Case | (kgf/cm) | with 85° C. and 85 RH % |
| Example 1 | 1.5 | 1.2 |
| Example 2 | 1.6 | 1.2 |
| Example 3 | 1.2 | 0.8 |
| Example 4 | 1.0 | 0.9 |
| Comparative | 1.1 | 0.6 |
| example 1 | | |
| Comparative | 1.0 | 0.6 |
| example 2 | | |

The results in Table 2 show that the initial values of Examples 1 to 4 were relatively higher in the range of 1.0 to 16 kgf/cm with comparison to Comparative Example 2 treated without coating the insulating layer, whereas Comparative Example 1 using the thermosetting resin had a similar value with Comparative Example 2. The reason is considered that the bonding by the melting of the anisotropic conductive adhesive is not prosecuted to be a help to the bonding force since the insulating layer coated on the TCP is not softened by the heat and pressure applied in the initial step of the circuit connection process.

Further, regarding the bonding force after leaving alone for 100 hours with a temperature of 85° C. and a relative humidity of 85RH %, the bonding force values for Comparative Examples 1 and 2 were reduced more than about 40%. The reason is considered that the aging of the adhesive is occurred since the moisture is more easily penetrated into the interface between the anisotropic conductive adhesive and TCP under the circumstance of the high temperature and the high humidity.

On the contrary, it is determined that, in case of Examples 1 to 4, the reliability of the bonding force is superior even after leaving alone for a long time since the melting bonding with the anisotropic conductive adhesive is occurred.

### INDUSTRIAL APPLICABILITY

In case of connecting the microcircuits using the anisotropic conductive adhesive containing conductive particles according to the present invention, a short-circuit due to the conductive particles is prevented, the degree of dispersion is even, a reliability of adhesion is superior, and conduction defect is removed.

Although the embodiment of the invention illustrates mainly the case of the anisotropic conductive adhesive component to connect the microcircuits, the method of connecting the microcircuits using a conductive adhesive component is also comprised within the scope of the invention.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

1. A method for connecting microcircuits comprising the steps of:
(a) generating an insulating resin solution;
(b) applying the resin solution to each circuit board having circuit patterns;
(c) aligning the circuit boards to face each other so that electrodes of the circuit boards face each other, in order to connect the corresponding electrodes of the circuit patterns formed in each circuit board;
(d) positioning an anisotropic conductive adhesive between the circuit boards;
(e) heating the circuit boards; and
(f) applying a predetermined pressure to an opponent side to a side applied by the anisotropc conduction adhesive so that corresponding electrodes are connected each other.

2. The method of claim 1, wherein in the (a) step said resin solution is prepared by dissolving a thermoplastic resin having a softening point in the range of 60 to 150° C. or a compound of the thermoplastic resin into a soluble solvent.

3. The method of claim 2, wherein the thermoplastic resin is selected from the group of consisting of polyethylene resin, ethylene copolymer resin, ethylene vinyl acetate copolymer resin, ethylene-acrylic acid copolymer resin, ethylene acrylic acid ester copolymer resin, poly amide resin, poly ester resin, styrene butadiene copolymer resin, ethylene-propylene copolymer resin, acrylic acid ester rubber, acrylonitrile-butadiene copolymer resin, phenoxy resin, thermoplastic epoxy resin, poly urethane resin, poly vinyl acetal resin and poly vinyl butilal resin.

4. The method of claim 1, wherein in the (a) step said resin solution is prepared by dissolving thermoplastic resin having a softening point in the range of 80 to 120° C. or a compound of the thermoplastic resin into a soluble solvent.

5. The method of claim 1, wherein in the (b) step said insulating film layer has a thickness of 0.1 to 5 μm on the circuit board.

6. The method of claim 1, wherein in the (b) step said insulating film layer has a thickness of 0.3 to 3 μm on the circuit board.

7. The method of claim 1, wherein the anisotropic conductive adhesive includes an insulating component, and conductive particles dispersed in the insulating component.

8. The method of claim 1, wherein in the (b) step said insulating film layer is formed on a plain portion and a side portion of the circuit patterns and a bottom portion of the circuit board.

9. The method of claim 1, wherein in the (b) step said insulating film layer is formed on a side portion of the circuit pattern and a bottom portion of the circuit board.

10. A connection structure of microcircuits comprising:
a first circuit board having first circuit patterns;
a second circuit board having second circuit patterns corresponding to the first circuit patterns;
conductive particles positioned between the first circuit board and the second circuit board for connecting mutually corresponding electrodes in the first circuit patterns and the second circuit patterns;
an insulating component positioned between the first circuit board and the second circuit board, the insulating component including the conductive particles; and
an insulating film layer applied on the first and second circuit patterns and the first and second circuit boards.

11. The connection structure of claim 10, wherein the corresponding electrodes have a predetermined plain area.

12. The connection structure of claim 10, wherein the corresponding electrodes include a front portion and side potions.

13. The connection structure of claim 10, wherein the insulating film layer is formed on side portions of the electrodes and a bottom portion of the circuit board.

14. The connection structure of claim 10, wherein the insulating film layer has a thickness of 0.1 to 5 μm.

15. The connection structure of claim 10, wherein the insulating film layer has a thickness of 0.3 to 3 μm.

16. The connection structure of claim 10, wherein the insulating film layer is made of a thermoplastic resin.

17. The connection structure of claim 16, wherein the thermoplastic resin is selected from the group of consisting of polyethylene resin, ethylene copolymer resin, ethylene vinyl acetate copolymer resin, ethylene-acrylic acid copolymer resin, ethylene acrylic acid ester copolymer resin, poly amide resin, poly ester resin, styrene butadiene copolymer resin, ethylene-propylene copolymer resin, acrylic acid ester rubber, acrylonitrile-butadiene copolymer resin, phenoxy resin, thermoplastic epoxy resin, poly urethane resin, poly vinyl acetal resin and poly vinyl butilal resin.
